(19) United States
(12) Patent Application Publication
(10) Pub. No.: US 2021/0182723 A1
(43) Pub. Date: Jun. 17, 2021

(54) APPARATUS AND METHOD FOR QUANTUM CIRCUIT SYNTHESIS USING HARDWARE-SPECIFIC CONSTRAINTS

(71) Applicant: Intel Corporation, Santa Clara, CA (US)

(72) Inventors: Albert Schmitz, Westminster, CO (US); Sonika Johri, Portland, OR (US); Anne Matsuura, Portland, OR (US)

(21) Appl. No.: 16/714,267

(22) Filed: Dec. 13, 2019

(51) Int. Cl. G06N 10/00; G06F 11/36

(52) U.S. Cl. CPC G06N 10/00; G06F 11/3688

(57) ABSTRACT

Apparatus and method for hardware-specific quantum circuit synthesis. For example, one embodiment of an apparatus comprises: one or more memory and/or storage devices to store quantum computation specifications and hardware-specific constraints associated with a quantum processor; and a quantum circuit synthesizer to generate a hardware-optimal quantum circuit based on the quantum computation specifications and the hardware-specific constraints.

### BACKGROUND

### Field of the Invention

The embodiments of the invention relate generally to the field of quantum computing. More particularly, these embodiments relate to an apparatus and method for quantum circuit synthesis using hardware-specific constraints.

### Description of the Related Art

Quantum computing refers to the field of research related to computation systems that use quantum mechanical phenomena to manipulate data. These quantum mechanical phenomena, such as superposition (in which a quantum variable can simultaneously exist in multiple different states) and entanglement (in which multiple quantum variables have related states irrespective of the distance between them in space or time), do not have analogs in the world of classical computing, and thus cannot be implemented with classical computing devices.

### BRIEF DESCRIPTION OF THE DRAWINGS

A better understanding of the present invention can be obtained from the following detailed description in conjunction with the following drawings, in which:

FIGS. 1A-1F illustrate various views of an example quantum dot device, in accordance with one embodiment;

FIG. 2 illustrates one embodiment of an apparatus for performing quantum circuit synthesis based on hardware-specific constraints;

FIG. 3 illustrates an example quantum circuit comprising a plurality of CNOT gates and a Z-rotation gate;

FIG. 4 illustrates a visualization of different paths in a Pauli frame graph (PFG);

FIGS. 5A-B illustrate two examples of synthesized circuits which include rotations and CNOT gates; and

FIG. 6 illustrates a method in accordance with one embodiment of the invention.

### DETAILED DESCRIPTION

In the following description, for the purposes of explanation, numerous specific details are set forth in order to provide a thorough understanding of the embodiments of the invention described below. It will be apparent, however, to one skilled in the art that the embodiments of the invention may be practiced without some of these specific details. In other instances, well-known structures and devices are shown in block diagram form to avoid obscuring the underlying principles of the embodiments of the invention.

### Introduction

A quantum computer uses quantum-mechanical phenomena such as superposition and entanglement to perform computations. In contrast to digital computers which store data in one of two definite states (0 or 1), quantum computation uses quantum bits (qubits), which can be in superpositions of states. Qubits may be implemented using physically distinguishable quantum states of elementary particles such as electrons and photons. For example, the polarization of a photon may be used where the two states are vertical polarization and horizontal polarization. Similarly, the spin of an electron may have distinguishable states such as “up spin” and “down spin.”

Qubit states are typically represented by the bracket notations |0> and |1>. In a traditional computer system, a bit is exclusively in one state or the other, i.e., a ‘0’ or a ‘1.’ However, qubits in quantum mechanical systems can be in a superposition of both states at the same time, a trait that is unique and fundamental to quantum computing.

Quantum computing systems execute algorithms containing quantum logic operations performed on qubits. The sequence of operations is statically compiled into a schedule and the qubits are addressed using an indexing scheme. This algorithm is then executed a sufficiently large number of times until the confidence interval of the computed answer is above a threshold (e.g., ˜95+%). Hitting the threshold means that the desired algorithmic result has been reached.

Qubits have been implemented using a variety of different technologies which are capable of manipulating and reading quantum states. These include, but are not limited to quantum dot devices (spin based and spatial based), trapped-ion devices, superconducting quantum computers, optical lattices, nuclear magnetic resonance computers, solid-state NMR Kane quantum devices, electrons-on-helium quantum computers, cavity quantum electrodynamics (CQED) devices, molecular magnet computers, and fullerene-based ESR quantum computers, to name a few. Thus, while a quantum dot device is described below in relation to certain embodiments of the invention, the underlying principles of the invention may be employed in combination with any type of quantum computer including, but not limited to, those listed above. The particular physical implementation used for qubits is orthogonal to the embodiments of the invention described herein.

### Quantum Dot Devices

Quantum dots are small semiconductor particles, typically a few nanometers in size. Because of this small size, quantum dots operate according to the rules of quantum mechanics, having optical and electronic properties which differ from macroscopic entities. Quantum dots are sometimes referred to as “artificial atoms” to connote the fact that a quantum dot is a single object with discrete, bound electronic states, as is the case with atoms or molecules.

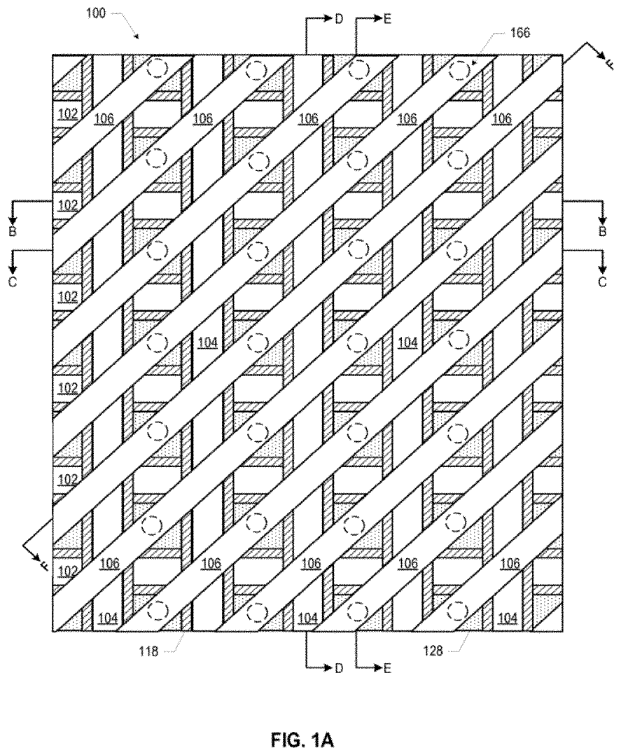

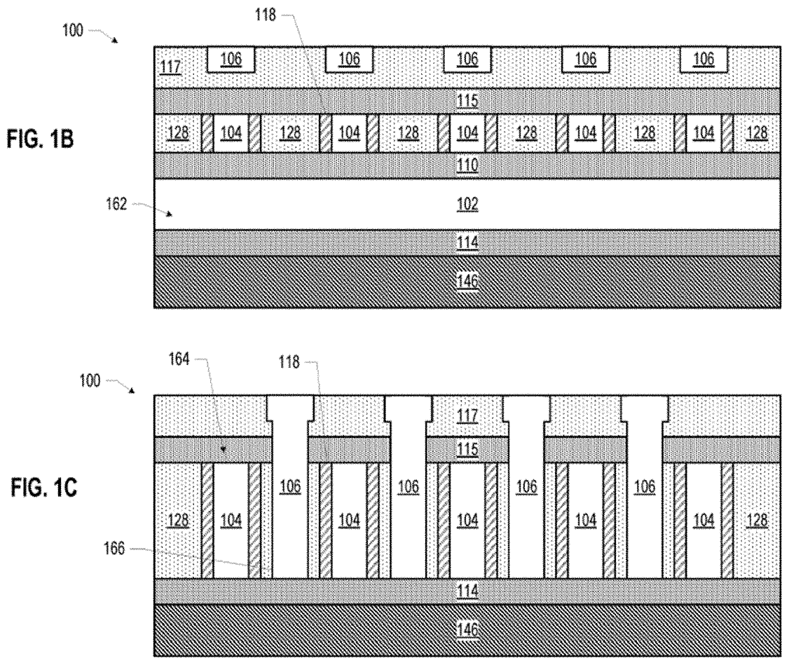

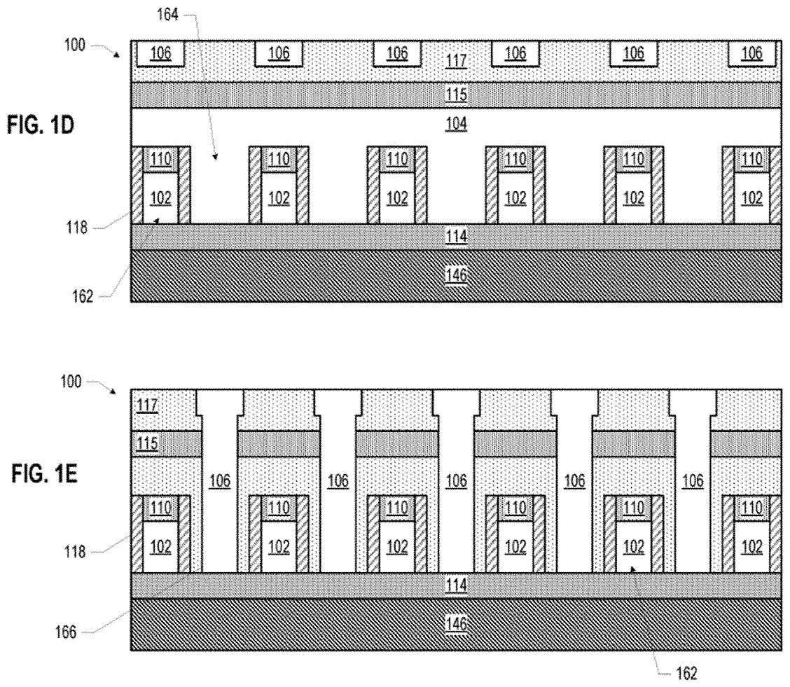

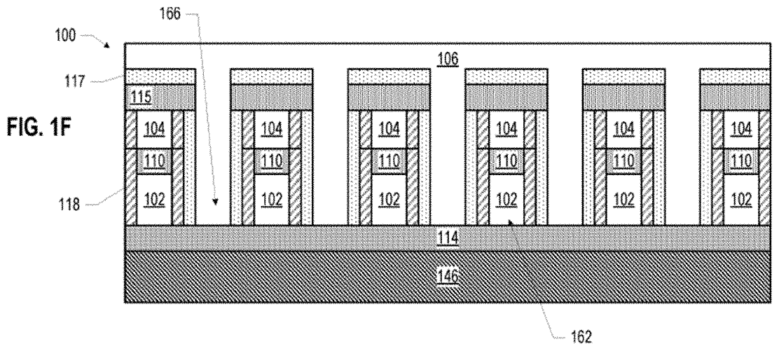

FIGS. 1A-1F are various views of a quantum dot device 100, which may be used with embodiments of the invention described below. FIG. 1A is a top view of a portion of the quantum dot device 100 with some of the materials removed so that the first gate lines 102, the second gate lines 104, and the third gate lines 106 are visible. Although many of the drawings and description herein may refer to a particular set of lines or gates as “barrier” or “quantum dot” lines or gates, respectively, this is simply for ease of discussion, and in other embodiments, the role of “barrier” and “quantum dot” lines and gates may be switched (e.g., barrier gates may instead act as quantum dot gates, and vice versa). FIGS. 1B-1F are side cross-sectional views of the quantum dot device 100 of FIG. 1A; in particular, FIG. 1B is a view through the section B-B of FIG. 1A, FIG. 1C is a view through the section C-C of FIG. 1A, FIG. 1D is a view through the section D-D of FIG. 1A, FIG. 1E is a view through the section E-E of FIG. 1A, and FIG. 1F is a view through the section F-F of FIG. 1A.

The quantum dot device 100 of FIG. 1 may be operated in any of a number of ways. For example, in some embodiments, electrical signals such as voltages, currents, radio frequency (RF), and/or microwave signals, may be provided to one or more first gate line 102, second gate line 104, and/or third gate line 106 to cause a quantum dot (e.g., an electron spin-based quantum dot or a hole spin-based quantum dot) to form in a quantum well stack 146 under a third gate 166 of a third gate line 106. Electrical signals provided to a third gate line 106 may control the electrical potential of a quantum well under the third gates 166 of that third gate line 106, while electrical signals provided to a first gate line 102 (and/or a second gate line 104) may control the potential energy barrier under the first gates 162 of that first gate line 102 (and/or the second gates 164 of that second gate line 104) between adjacent quantum wells. Quantum interactions between quantum dots in different quantum wells in the quantum well stack 146 (e.g., under different quantum dot gates) may be controlled in part by the potential energy barrier provided by the barrier potentials imposed between them (e.g., by intervening barrier gates).

Generally, the quantum dot devices 100 disclosed herein may further include a source of magnetic fields (not shown) that may be used to create an energy difference in the states of a quantum dot (e.g., the spin states of an electron spin-based quantum dot) that are normally degenerate, and the states of the quantum dots (e.g., the spin states) may be manipulated by applying electromagnetic energy to the gates lines to create quantum bits capable of computation. The source of magnetic fields may be one or more magnet lines, as discussed below. Thus, the quantum dot devices 100 disclosed herein may, through controlled application of electromagnetic energy, be able to manipulate the position, number, and quantum state (e.g., spin) of quantum dots in the quantum well stack 146.

In the quantum dot device 100 of FIG. 1, a gate dielectric 114 may be disposed on a quantum well stack 146. A quantum well stack 146 may include at least one quantum well layer 152 (not shown in FIG. 1) in which quantum dots may be localized during operation of the quantum dot device 100. The gate dielectric 114 may be any suitable material, such as a high-k material. Multiple parallel first gate lines 102 may be disposed on the gate dielectric 114, and spacer material 118 may be disposed on side faces of the first gate lines 102. In some embodiments, a patterned hardmask 110 may be disposed on the first gate lines 102 (with the pattern corresponding to the pattern of the first gate lines 102), and the spacer material 118 may extend up the sides of the hardmask 110, as shown. The first gate lines 102 may each be a first gate 162. Different ones of the first gate lines 102 may be electrically controlled in any desired combination (e.g., each first gate line 102 may be separately electrically controlled, or some or all the first gate lines 102 may be shorted together in one or more groups, as desired).

Multiple parallel second gate lines 104 may be disposed over and between the first gate lines 102. As illustrated in FIG. 1, the second gate lines 104 may be arranged perpendicular to the first gate lines 102. The second gate lines 104 may extend over the hardmask 110, and may include second gates 164 that extend down toward the quantum well stack 146 and contact the gate dielectric 114 between adjacent ones of the first gate lines 102, as illustrated in FIG. 1D. In some embodiments, the second gates 164 may fill the area between adjacent ones of the first gate lines 102/spacer material 118 structures; in other embodiments, an insulating material (not shown) may be present between the first gate lines 102/spacer material 118 structures and the proximate second gates 164. In some embodiments, spacer material 118 may be disposed on side faces of the second gate lines 104; in other embodiments, no spacer material 118 may be disposed on side faces of the second gate lines 104. In some embodiments, a hardmask 115 may be disposed above the second gate lines 104. Multiple ones of the second gates 164 of a second gate line 104 are electrically continuous (due to the shared conductive material of the second gate line 104 over the hardmask 110). Different ones of the second gate lines 104 may be electrically controlled in any desired combination (e.g., each second gate line 104 may be separately electrically controlled, or some or all the second gate lines 104 may be shorted together in one or more groups, as desired). Together, the first gate lines 102 and the second gate lines 104 may form a grid, as depicted in FIG. 1.

Multiple parallel third gate lines 106 may be disposed over and between the first gate lines 102 and the second gate lines 104. As illustrated in FIG. 1, the third gate lines 106 may be arranged diagonal to the first gate lines 102, and diagonal to the second gate lines 104. In particular, the third gate lines 106 may be arranged diagonally over the openings in the grid formed by the first gate lines 102 and the second gate lines 104. The third gate lines 106 may include third gates 166 that extend down to the gate dielectric 114 in the openings in the grid formed by the first gate lines 102 and the second gate lines 104; thus, each third gate 166 may be bordered by two different first gate lines 102 and two different second gate lines 104. In some embodiments, the third gates 166 may be bordered by insulating material 128; in other embodiments, the third gates 166 may fill the openings in the grid (e.g., contacting the spacer material 118 disposed on side faces of the adjacent first gate lines 102 and the second gate lines 104, not shown). Additional insulating material 117 may be disposed on and/or around the third gate lines 106. Multiple ones of the third gates 166 of a third gate line 106 are electrically continuous (due to the shared conductive material of the third gate line 106 over the first gate lines 102 and the second gate lines 104). Different ones of the third gate lines 106 may be electrically controlled in any desired combination (e.g., each third gate line 106 may be separately electrically controlled, or some or all the third gate lines 106 may be shorted together in one or more groups, as desired).

Although FIGS. 1A-F illustrate a particular number of first gate lines 102, second gate lines 104, and third gate lines 106, this is simply for illustrative purposes, and any number of first gate lines 102, second gate lines 104, and third gate lines 106 may be included in a quantum dot device 100. Other examples of arrangements of first gate lines 102, second gate lines 104, and third gate lines 106 are possible. Electrical interconnects (e.g., vias and conductive lines) may contact the first gate lines 102, second gate lines 104, and third gate lines 106 in any desired manner.

Not illustrated in FIG. 1 are accumulation regions that may be electrically coupled to the quantum well layer of the quantum well stack 146 (e.g., laterally proximate to the quantum well layer). The accumulation regions may be spaced apart from the gate lines by a thin layer of an intervening dielectric material. The accumulation regions may be regions in which carriers accumulate (e.g., due to doping, or due to the presence of large electrodes that pull carriers into the quantum well layer), and may serve as reservoirs of carriers that can be selectively drawn into the areas of the quantum well layer under the third gates 166 (e.g., by controlling the voltages on the quantum dot gates, the first gates 162, and the second gates 164) to form carrier-based quantum dots (e.g., electron or hole quantum dots, including a single charge carrier, multiple charge carriers, or no charge carriers). In other embodiments, a quantum dot device 100 may not include lateral accumulation regions, but may instead include doped layers within the quantum well stack 146. These doped layers may provide the carriers to the quantum well layer. Any combination of accumulation regions (e.g., doped or non-doped) or doped layers in a quantum well stack 146 may be used in any of the embodiments of the quantum dot devices 100 disclosed herein.

### Apparatus and Method for Quantum Circuit Synthesis Using Hardware-Specific Constraints

In the noisy, intermediate-scale quantum (NISQ) era of quantum computing, devices are primarily limited by the time before noise becomes detrimental to the outcome of the computation. This places an emphasis on identifying the fewest hardware operations to achieve the computation, often referred to as the “optimal” circuit.

However, the “optimality” of a given circuit can be highly hardware-specific due to limited communication between distant qubits as well as other timing and hardware constraints. Even for quantum processors constructed with the same architecture, corresponding qubits may behave differently (e.g., a qubit in one quantum processor may have a shorter decoherence time than the same qubit in another quantum processor).

Current implementations allow a user to specify any circuit (including poorly designed circuits), to a quantum compiler which must then take several optimization passes through the circuit to identify the optimal schedule and configuration parameters for the hardware, resulting in loss of performance and/or wasted cycles.

High-level optimizers are generally hardware-agnostic whereas lower-level optimizers include hardware-specific constraints (e.g., a scheduler pass may use information related to the qubit topology in a particular quantum processor). Thus, high-level optimizations which depend on the hardware are unexploited as they are obscured by the low-level expression of the circuit at the layer of the compiler (i.e., where hardware-specific constraints are introduced).

Current compilers with circuit synthesis components tend to use standard compute/uncompute techniques, where each individual piece of the algorithm is synthesized independently, and subsequent optimization passes are expected to minimize the cost. Thus, another inefficiency is the additional compilation time required to perform these multiple optimization passes.

One embodiment of the invention implements a framework for circuit synthesis which generates a near-optimal circuit based on a high-level representation of the computation to be performed, as specified by the user, and hardware-specific constraints associated with the quantum processor. IN particular, hardware constraints are evaluated during the synthesis, whereby choices related to how to translate and integrate the user's input include these constraints to reduce hardware-dependent overhead.

### A. Hardware-Specific Quantum Circuit Synthesizer Architecture

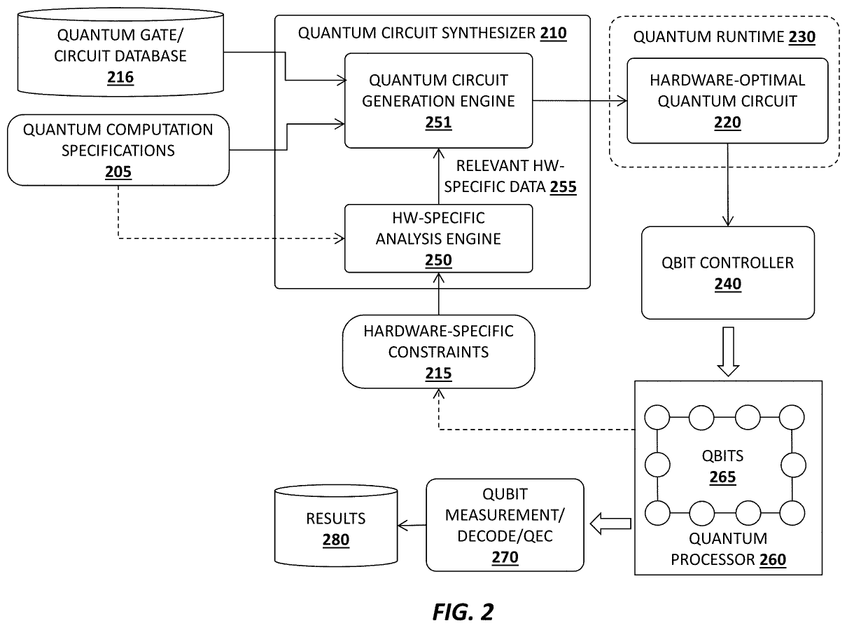

FIG. 2 illustrates one implementation of a quantum circuit synthesizer 210 which generates a hardware optimal quantum circuit 220 based on high level user input 205 specifying the computations to be performed and specified hardware constraints 215 associated with the quantum processor 260 (e.g., the number and arrangement of qubits, qubit-specific data such as decoherence times, etc). In one embodiment, the hardware-specific constraints 215 are entered by the user, read from a database in which hardware-specific data is stored for different quantum processors 260, and/or determined automatically through running test scripts on the quantum processor 260.

In one embodiment, regardless of how the hardware-specific constraints 215 are determined, they are incorporated into the quantum circuit generation process by a hardware-specific analysis engine 250, which identifies those hardware-specific features of the quantum processor 260 which are of particular relevance for the set of quantum computation specifications 205 provided by the user. For example, the specific arrangements and distances between qubits may be highly relevant for certain quantum circuits but not relevant (or only marginally relevant) for others. Similarly, the parallel processing capabilities of the quantum processor and/or qubit controller 240 (e.g., the number of qubits which can be concurrently controlled) may be of particular relevance for certain types of quantum algorithms. Thus, the hardware-specific analysis engine 250 evaluates the hardware-specific constraints 215 in view of the quantum computation specifications 205 to pass only relevant hardware-specific data 255 to the quantum circuit generation engine 251. The quantum circuit generation engine 251 then generates the hardware-optimal quantum circuit 220 in view of relevant hardware-specific data 255 in addition to the quantum computation specifications 205 provided by the user.

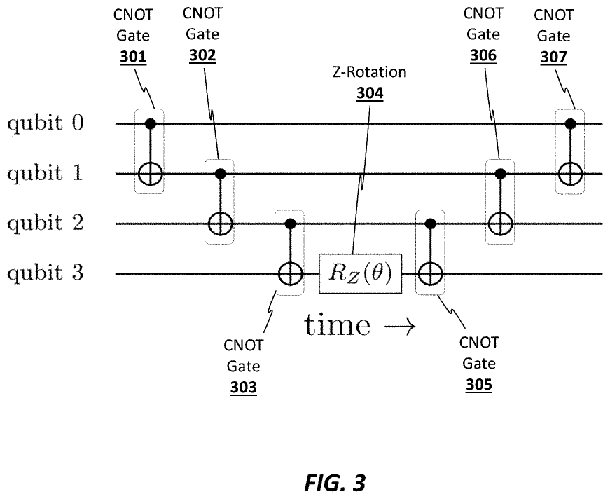

As illustrated, the quantum circuit generation engine 251 may also rely on a quantum gate/circuit database 216 to access data associated with various types of quantum gates and/or circuits including, but not limited to, those described herein. For example, referring to FIG. 3, qubit-level specifications for implementing CNOT gates 301-303, 305-307 and Z-rotation gates 304 may be stored in the quantum gate/circuit database 216.

Once generated by the quantum circuit synthesizer 210, the hardware-optimal quantum circuit 220 executes within the context of a quantum runtime 230, generating sequences of qubit control commands which are executed by a qubit controller 240. In one embodiment, the qbit controller 240 generates corresponding sequences of analog control pulses to manipulate the qubits 265 of the quantum processor 260 in accordance with the hardware-optimal quantum circuit 220 (e.g., using analog wave generators (AWG) with code-triggered pulse generator (CTPG) units or similar arrangements).

A qubit measurement unit 270 takes measurements of the qubits 265 and generates results 280 in accordance with the quantum circuit 220 and runtime 230. In one embodiment, the qubit measurement unit 270 includes a measurement discrimination unit (MDU) for converting the analog output from the quantum processor into binary results and may also include a quantum decoder and/or quantum error correction (QEC) unit. Note that the set of qubits 265 are sometimes referred to herein as the “quantum memory.”

### B. Use Case Examples

Two specific use cases are described below for the purpose of illustration: (i) the user provides a Hamiltonian or other high level description; and (ii) the user provides a generic algorithm described in a product-of-Pauli-rotations form.

With respect to use case (i) the user provides a Hamiltonian or high-level description used to simulate the time-evolution of physical systems commonly used in materials, chemistry, and physics research. In this implementation, the user inputs a collection of Hamiltonian terms which represent physical quantities, each with a numerical coefficient, as well as the time interval of the simulation, the desired accuracy, the initial state of the system, and the “measurements” or outputs to be obtained after the simulation is complete.

In use case (ii), the user provides a generic algorithm described in a product-of-Pauli-rotations form. For example, in one embodiment, the user inputs an ordered list of Pauli operators which represent physical quantities of the qubit memory, each with a numerical coefficient as well as the “measurements” or outputs to be obtained after the process is complete.

### C. Overview of Quantum Circuit Synthesizer Operations

In use case (i), one embodiment of the quantum circuit synthesizer 210 performs Trotterization of the time-evolution operator, or simply “Trotterization” for short. Each term provided by the quantum computation specifications 205 submitted by the user represents a part of the evolution of the simulated system. Based on the context of the user input 205 (e.g., where the input terms represent bosons, fermions, spins, etc.), the quantum circuit synthesizer 210 translates these terms and their coefficients into a list of Pauli operators, each with a numerical coefficient (e.g., similar to the inputs of use case (ii)).

Each of these Pauli operators represents an action to be performed by the qubit controller 240 on the qubit memory 265 which is parameterized by the input coefficient associated with that Pauli operator. This action is referred to as a Pauli rotation and the parameter is referred to as a rotation angle. Once one Pauli rotation for each of the Pauli operators has been applied to the qubit memory 265, the state of that memory represents the approximate evolution of the simulated system by a small interval of time as determined by the total simulation time and accuracy. These actions are then repeated until the total simulation time is equal to the total time interval as provided in the user specifications 205.

Certain embodiments may require the user to change the coefficients as a function of simulation time. This can be handled by simply changing the rotation angles according to the user's specifications 205. For a single time step of Totterization (all Pauli rotations are applied once), the order in which the Pauli rotations are applied does affect the outcome, but the variation is generally within the tolerances specified by the user. Thus, the order of the user's input data for this embodiment is irrelevant.

For the product-of-Pauli-rotations use case (ii), the actions taken by the qubit controller 240 are essentially the same. Every Pauli operator provided by the user translates into a Pauli rotation that must be applied to the qubit memory as parametrized by the numerical coefficient provided. However, in this use case, the final state of the system can be highly dependent on the order in which these Pauli rotations are applied, thus the order of the user's inputs is important. Moreover, based upon certain criteria that can be determined by the Pauli operators directly, the order of some Pauli rotations can be permuted with no effect on the computation, a process referred to herein as “commutation.” Commutation can be used to increase the efficiency of the computation as described below.

### D. Circuit Synthesis

For both use-cases described above, the quantum controller 240 applies a sequence of parameterized Pauli rotations to the qubit memory 265. Most systems do not directly support Pauli rotations for arbitrary Pauli operators and rotation angles. Consequently, any complier accepting the user inputs 205 described herein must decompose such Pauli rotations into a sequence of operations or gates which are 1) universal (e.g., they can be used to express any Pauli rotation and more broadly any transformation on the qubit memory), and 2) they are “nearly” supported by the hardware (e.g., they can be efficiently decomposed directly into hardware-specific operations). This process is referred to herein as circuit synthesis, and the ordered list of gates as the hardware-optimal quantum circuit 220.

It is assumed here that the operations can be described by the Clifford+R_{Z} gate set which can be roughly divided into two subsets. The first subset contains all Clifford gates. A typical example might be, but is not limited to, the set containing the CNOT, Hadamard, and phase gates. The second subset contains a single gate parameterized by a numerical value, R_{Z}(θ), referred to as the single qubit Z-rotation gate, where θ represents the numerical value. It can be demonstrated that any Pauli rotation with rotation angle θ can be performed by a circuit of the form C R_{Z}(θ) C⁻¹, where C represents a non-unique sequence of operations exclusively from the Clifford gates, C⁻¹ represents another sequence of Clifford gates which undoes C, and where the qubit R_{Z} (θ) is applied to is highly dependent on C.

This decomposition implementation is referred to herein as the compute/uncompute synthesis. Compute/uncompute synthesis represents the current standard for circuit synthesis of algorithms of this form. One must also choose a standard method for constructing C. For most Clifford gate sets which contain a two-qubit gate such as CNOT, this is done with “ladder circuits” whereby for example, a CNOT is performed between qubits 0 and 1 followed by a CNOT between qubits 1 and 2 and so on and the rotation is applied to the last qubit in the sequence.

An example of this is shown in FIG. 3 for applying a Z₀Z₁Z₂Z₃ Pauli rotation. Finally, to address the order of when to apply which Pauli rotation, the order as provided by the user is typically used in both use-cases described above, though there exists techniques to reduce the number of gates for specific instances of the Hamiltonian use-case.

### E. Pauli Frame Graph (PFG) Techniques for Circuit Synthesis

This embodiment of the invention is first described for use case (i) followed by a description of how it is extended to use-case (ii).

To create an efficient circuit which performs one time step of the Trotterization algorithm, the order in which the Pauli rotations are applied as well as the qubit on which the Z-rotation is applied are exploited. An analogous situation which is helpful for understanding these techniques is the “traveling shopper problem.” Suppose a shopper needs to buy a specific set of items on a list from several stores. Many stores sell each item and no store sells all the items. The shopper starts from home and wants to return home after shopping. Once at a store, the shopper can easily determine which items are available at that store and can determine the nearest store to his/her current location which has any item on the list. The shopper can also determine an efficient route back home. The shopper would like to determine the most efficient route and a particular sequence of stores which allows the shopper to buy all the items on the list and return home.

For the Trotterization algorithm use-case, the list of items corresponds to the set of Pauli operators for which a Pauli rotation must be applied. A store in the analogy corresponds to a Pauli frame comprising mathematical objects that can be represented by a collection of binary vectors of a size that scales with the number of qubits used. Pauli frames have three important properties: 1) the Pauli frame describes roughly the current state of the qubit memory (technically only for a specific set of initial states of the qubit memory), 2) Clifford gates transform Pauli frames in a nearly unique way so the action of Clifford gates on the qubit memory can be tracked via Pauli frames, and 3) Pauli frames can be used to infer how a Z-rotation gate applied in the current Pauli frame (tracking the action of a sequence of Clifford gates) effectively applies a Pauli rotation.

Thus, for example, in FIG. 3, the first three CNOT gates 301-303 transform the starting Pauli frame or origin frame to some other Pauli frame. From that frame, it can be determined that a Z-rotation gate 304 on qubit 3 effectively applies a Z₀Z₁Z₂Z₃ Pauli rotation, assuming a return to the origin frame, which is accomplished by the last three CNOT gates 305-307. Construction of the Pauli frame graph (PFG) can be visualized where each Pauli frame is represented as a node, and two nodes are connected if and only if there is a single Clifford gate which connects the two frames these nodes represent. Thus, returning to the traveler shopping problem, the PFG is effectively a road map of stores.

An ordering of the Pauli operators may be determined such that the Pauli rotations are to be applied in that order. With compute\uncompute techniques, the decomposition of this to a circuit would have the general form:

C₀R_{Z}(θ₀)C₀⁻¹C₁R_{Z}(θ₁)C₁⁻¹ . . . Cₖ₋₁R_{Z}(θ)Cₖ₋₁⁻¹CₖR_{Z}(θₖ)Cₖ⁻¹ (1)

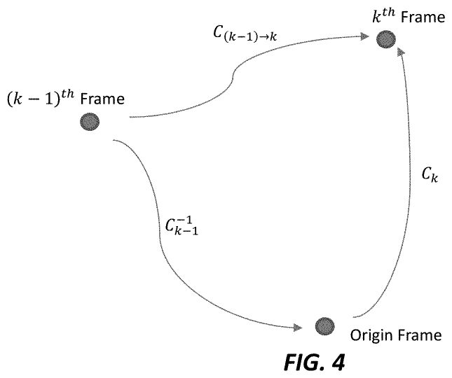

Note that in between the k^{th} and (k−1)^{th} Z-rotation gate there is a Cₖ₋₁⁻¹ Cₖ sequence of Clifford gates which can be highly simplified to be some other sequence of Clifford gates, Cₖ₋₁⁻¹Cₖ≅C_{k-1→k}. Regardless of that sequence, the collective action on the qubit memory must be the same and thus both must transform the Pauli frame at the time of the (k−1)^{th} Z-rotation to that of the Pauli frame at the time of the k^{th} Z-rotation. In the PFG, Cₖ₋₁⁻¹Cₖ represents a path which starts at the (k−1)^{th} Pauli frame, goes back to the origin frame and then goes to the k^{th} Pauli frame. Clearly, this is not as efficient as C_{k-1→k} which presumably goes directly from the (k−1)^{th} frame to the k^{th} frame as shown in FIG. 4. Such a path can be determined with moderate computational efficiency based upon the k^{th} and the (k−1)^{th} frame. Thus, a single Trotterization time step may be completed by traversing a path in the PFG such that every one of these frames lies on that path and the path returns to the origin, a path referred to as a Hamiltonian cycle. But this does not express the full power of PFG methods, because the Hamiltonian cycle of the above equation is chosen inefficiently by the compute/uncompute method. That is, for any given Pauli operator, there are several Pauli frames from which the corresponding Pauli rotation can be realized.

This is analogous to the traveler shopping problem where there are several stores from which the shopper can buy a given item. In addition, like the traveler shopping problem, for a given Pauli operator, a circuit can be efficiently determined which minimizes the number of 2-qubit gates needed to reach a (non-unique) Pauli frame capable of realizing the corresponding Pauli rotation (e.g., the shopper can calculate the distance to the nearest store which carries a given item). Consequently, the set of Pauli frames visited by a valid Hamiltonian cycle is not unique and can be chosen to further increase the efficiency of the circuit. This highlights the basic task underlying PFG techniques of circuit synthesis: Find a path in the PFG which starts at the origin, visits a frame capable of realizing a Pauli rotation for each user-input term and returns to the origin. Furthermore, one embodiment attempts to find the shortest possible path in terms of 2-qubit gates.

To extend PFG methods for circuit synthesis to use-case (ii), it must be recognized that the freedom in use-case (i) is lost due to the importance of the order in which the Pauli rotations are applied. This dependency can be encapsulated by translating the user inputs into a directed acyclic graph (DAG), similar to techniques for encoding scheduling dependencies in classical computing architectures. Each node in the DAG represents a Pauli operator in the user's input list and a directed edge connects two nodes if and only if the two Pauli rotations they represent cannot be commuted, where the head of the arrow points at the Pauli operator which appears first in the list. Once translated into DAG form, one embodiment of the invention uses typical DAG-based scheduling techniques where at each point in the synthesis process, a list of Pauli operators which are free of dependencies is maintained, the PFG is searched to advance the path, and once a Pauli rotation is realized, the dependency is updated and any operators now free of dependencies are added to the search list. Once the entire list has been scheduled, an efficient path back to the origin frame is determined.

### F. PFG Greedy Search Techniques

The traveler shopping problem (TShP) is a generalization of the traveling salesman problem (TSP), which is a computationally difficult problem to solve exactly (finding the exact minimum path between locations visited by a salesman). However, many highly developed heuristics exist for approximate solutions to TSP which are adapted in one embodiment of the invention to the traveler shopping problem.

In particular, a greedy search algorithm is used in one embodiment, where at each step in the search the closest item/Pauli operator is targeted. Still, because the store/frame is not unique (a property unique to TShP) and many items/Pauli operators may have the same minimum distance, a cost metric is also considered for choosing among the many possibilities. In the hardware agnostic case, there are two major considerations, 1) whether or not a move takes the result closer to the remaining Pauli operators, and 2) whether an operation can be performed in parallel with other operations already decided on.

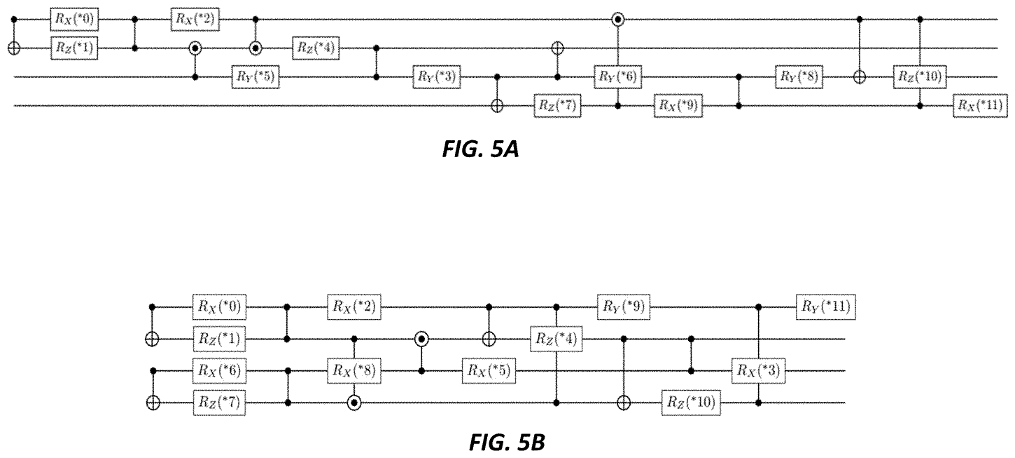

FIGS. 5A-B illustrate examples of two synthesized circuits for the same Hamiltonian input (use-case i) using different cost metrics. Even though they use the same number of two-qubit gates, the circuit in FIG. 5B should, for ideal hardware, take less time.

### G. Circuit Synthesizer Using PFG Greedy Search

One embodiment of the quantum circuit synthesizer 210 implements PFG greedy search techniques for circuit synthesis. In particular, this embodiment incorporates hardware constraints 215 which include, but are not limited to, specific qubit connectivity and hardware specific timing constraints, each of which are described below.

Hardware Connectivity—For most systems, not every qubit can communicate directly with every other qubit, but are limited to communicating with only a few adjacent qubits. When a quantum operation requires an interaction between distant qubits, the common solution is to apply a sequence of SWAP operations to effectively move the information contained in the two logical qubits to two physical qubits which can interact or communicate directly to achieve the desired outcome. Each SWAP costs three CNOT gates, so the cost of an interaction between two logical qubits is proportional to the distance between the physical qubits on which they reside. In one embodiment, this type of cost is encoded in the PFG by trimming edges in the graph. That is, instead of connecting Pauli frames corresponding to all possible Clifford gates in the gate set, only those gates between qubits which are supported by the hardware are included. Thus, the cost metric now reflects the actual cost to perform the operation. This allows the quantum circuit synthesizer 210 to avoid choices that nominally improve performance in the ideal case, by are actually costly due to limited qubit connectivity.

Hardware Specific Timing Issues for Parallel Scheduling—In the above description, increased parallelism is included in the cost metric for improved synthesis. However due to control-line multiplexing, fundamental hardware limitations or other control constraints, certain hardware implementations will not support this maximal parallelism. Thus, in one implementation, these limitations are encoded in the hardware constraints 215 used by the quantum circuit synthesizer 210 to avoid choices based on nominal parallelism which will not actually result is a shorter run-time on hardware. Note in both cases, the quantum circuit synthesizer 210 makes scheduling choices to maximize efficiency based upon specified hardware constraints 215. Consequently, evaluating such details at the level of circuit synthesis effectively synthesizes and schedules the quantum circuit simultaneously which can greatly improve the compiler runtime by integrating parts of the stack.

Thus, one embodiment of the invention comprises a quantum circuit synthesizer 210 implemented in software, circuitry, or any combination thereof which incorporates hardware-specific data to generate a hardware-optimal quantum circuit 220. In one particular implementation, high level quantum computation specifications are input by a user in a form which cannot be directly described as a circuit. These embodiments simultaneously increase the efficiency of the compilation and computation, while providing a simpler user interface for quantum algorithms. This one-step synthesis, optimization and scheduling boosts compiler performance by integrating some functionalities of the quantum stack.

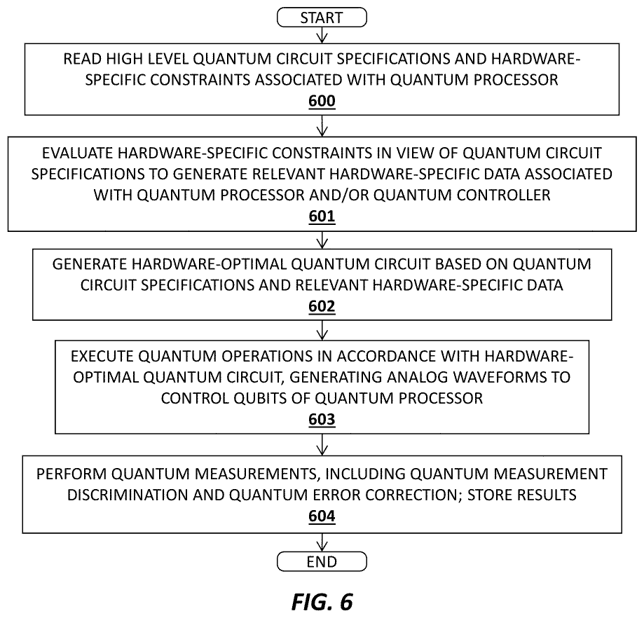

FIG. 6 illustrates one embodiment of a method for performing hardware-optimized quantum circuit synthesis. The illustrated method may be implemented on the various quantum architectures described herein, but is not limited to any particular architecture.

At 600, high level quantum circuit specifications and hardware-specific constraints are read from a memory and/or storage device. At 601, hardware-specific constraints are evaluated in view of the quantum circuit specifications to generate relevant hardware-specific data associated with the quantum processor and/or quantum controller. For example, in one embodiment, only those hardware-specific features which are relevant to the quantum circuit specifications are included in the relevant hardware-specific data.

At 602, a hardware-optimal quantum circuit is generated based on an evaluation of both the quantum circuit specifications and relevant hardware-specific data. As mentioned, in one embodiment, the scheduling decisions are made to maximize efficiency based upon the hardware-specific data which effectively synthesizes and schedules the quantum circuit simultaneously, thereby improving the quantum runtime by integrating parts of the stack.

At 603, quantum operations are executed in accordance with the hardware-optimal quantum circuit. For example, in one embodiment, an analog wave generator (AWG) and/or code-triggered pulse generator (CTPG) generates sequences of analog pulses based on the hardware-optimal quantum circuit.

At 604, quantum measurements of one or more qubits are performed. A quantum measurement unit may include measurement discrimination and quantum error correction circuitry/logic to discriminate qubit measurement values and perform error correction if required. The quantum measurement unit may convert the analog measurements to digital data which is stored in a memory and/or storage device.

### Examples

The following are example implementations of different embodiments of the invention.

Example 1. An apparatus comprising: one or more memory and/or storage devices to store quantum computation specifications and hardware-specific constraints associated with a quantum processor; and a quantum circuit synthesizer to generate a hardware-optimal quantum circuit based on the quantum computation specifications and the hardware-specific constraints.

Example 2. The apparatus of example 1 wherein the quantum circuit synthesizer comprises a hardware-specific analysis engine to identify relevant hardware-specific data based on the hardware-specific constraints and the quantum computation specifications.

Example 3. The apparatus of example 2 wherein to identify relevant hardware-specific data, the hardware-specific analysis engine is to determine whether and/or to what extent a specific hardware constraint will have with respect to implementation of the quantum computation specifications.

Example 4. The apparatus of example 2 further comprising a database or other storage implementation to store quantum gate/circuit data; a quantum circuit generation engine of the quantum circuit synthesizer to use at least a portion of the quantum gate/circuit data to generate the hardware-optimal circuit based on the quantum computation specifications and the relevant hardware-specific data.

Example 5. The apparatus of example 1 wherein the hardware-specific constraints are to be provided by a user, read from a database in which hardware-specific data is stored for different quantum processors, and/or determined automatically through running test scripts on the quantum processor.

Example 6. The apparatus of example 1 wherein the hardware-specific constraints include arrangements and distances between qubits of a quantum processor, parallel processing capabilities of the quantum processor and/or a qubit controller, and/or qubit specific characteristics related to quantum control and/or measurements.

Example 7. The apparatus of example 1 further comprising: execution circuitry to implement the hardware-optimal quantum circuit within a quantum runtime to generate sequences of qubit control commands.

Example 8. The apparatus of example 7 further comprising a quantum controller to generate corresponding sequences of analog control pulses to manipulate the qubits of the quantum processor in response to the sequences of qubit control commands.

Example 9. The apparatus of example 7 wherein the sequences of qubit control commands are to specify a sequence of parameterized Pauli rotations to one or more qubits of the quantum processor.

Example 10. The apparatus of example 9 further comprising: a qubit measurement unit comprising measurement discrimination circuitry/logic to measure values of one or more of the qubits; and quantum error correction circuitry/logic to perform quantum error corrections on the values if an error is detected.

Example 11. A method comprising: storing quantum computation specifications and hardware-specific constraints associated with a quantum processor in one or more memory devices and/or storage devices; and generating a hardware-optimal quantum circuit based on the quantum computation specifications and the hardware-specific constraints.

Example 12. The method of example 11 further comprising identifying relevant hardware-specific data based on the hardware-specific constraints and the quantum computation specifications.

Example 13. The method of example 13 further comprising determining whether and/or to what extent a specific hardware constraint will have with respect to implementation of the quantum computation specifications to identify relevant hardware-specific data.

Example 14. The method of example 12 further comprising storing quantum gate/circuit data in a database or other storage device; using at least a portion of the quantum gate/circuit data to generate the hardware-optimal circuit.

Example 15. The method of example 11 wherein the hardware-specific constraints are to be provided by a user, read from a database in which hardware-specific data is stored for different quantum processors, and/or determined automatically through running test scripts on the quantum processor.

Example 16. The method of example 11 wherein the hardware-specific constraints include arrangements and distances between qubits of a quantum processor, parallel processing capabilities of the quantum processor and/or a qubit controller, and/or qubit-specific characteristics related to quantum control and/or measurements.

Example 17. The method of example 11 further comprising: generate sequences of qubit control commands in response to implementing the hardware-optimal quantum circuit within a quantum runtime.

Example 18. The method of example 17 further comprising: generating corresponding sequences of analog control pulses to manipulate the qubits of the quantum processor in response to the sequences of qubit control commands.

Example 19. The method of example 17 wherein the sequences of qubit control commands are to specify a sequence of parameterized Pauli rotations to one or more qubits of the quantum processor.

Example 20. The method of example 19 further comprising: measuring values associated with one or more of the qubits; performing error correction on the values to generate corrected values if an error is detected; and storing results comprising the values and/or the corrected values.

Example 21. A machine-readable medium having program code stored thereon which, when executed by a machine, causes the machine to perform the operations of: storing quantum computation specifications and hardware-specific constraints associated with a quantum processor in one or more memory devices and/or storage devices; and generating a hardware-optimal quantum circuit based on the quantum computation specifications and the hardware-specific constraints.

Example 22. The machine-readable medium of example 21 further comprising program code to cause the machine to perform the operations of: identifying relevant hardware-specific data based on the hardware-specific constraints and the quantum computation specifications.

Example 23. The machine-readable medium of example 23 further comprising program code to cause the machine to perform the operations of: determining whether and/or to what extent a specific hardware constraint will have with respect to implementation of the quantum computation specifications to identify relevant hardware-specific data.

Example 24. The machine-readable medium of claim 22 further comprising program code to cause the machine to perform the operations of: storing quantum gate/circuit data in a database or other storage device; using at least a portion of the quantum gate/circuit data to generate the hardware-optimal circuit.

Example 25. The machine-readable medium of claim 21 wherein the hardware-specific constraints are to be provided by a user, read from a database in which hardware-specific data is stored for different quantum processors, and/or determined automatically through running test scripts on the quantum processor.

Example 26. The machine-readable medium of claim 21 wherein the hardware-specific constraints include arrangements and distances between qubits of a quantum processor, parallel processing capabilities of the quantum processor and/or a qubit controller, and/or qubit-specific characteristics related to quantum control and/or measurements.

Example 27. The machine-readable medium of claim 21 further comprising program code to cause the machine to perform the operations of: generate sequences of qubit control commands in response to implementing the hardware-optimal quantum circuit within a quantum runtime.

Example 28. The machine-readable medium of claim 27 further comprising program code to cause the machine to perform the operations of: generating corresponding sequences of analog control pulses to manipulate the qubits of the quantum processor in response to the sequences of qubit control commands.

Example 29. The machine-readable medium of claim 27 wherein the sequences of qubit control commands are to specify a sequence of parameterized Pauli rotations to one or more qubits of the quantum processor.

Example 30. The machine-readable medium of claim 29 further comprising program code to cause the machine to perform the operations of: measuring values associated with one or more of the qubits; performing error correction on the values to generate corrected values if an error is detected; and storing results comprising the values and/or the corrected values.

In the above detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments. Terms like “first,” “second,” “third,” etc. do not imply a particular ordering, unless otherwise specified.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous.

Embodiments of the invention may include various steps, which have been described above. The steps may be embodied in machine-executable instructions which may be used to cause a general-purpose or special-purpose processor to perform the steps. Alternatively, these steps may be performed by specific hardware components that contain hardwired logic for performing the steps, or by any combination of programmed computer components and custom hardware components.

As described herein, instructions may refer to specific configurations of hardware such as application specific integrated circuits (ASICs) configured to perform certain operations or having a predetermined functionality or software instructions stored in memory embodied in a non-transitory computer readable medium. Thus, the techniques shown in the figures can be implemented using code and data stored and executed on one or more electronic devices (e.g., an end station, a network element, etc.). Such electronic devices store and communicate (internally and/or with other electronic devices over a network) code and data using computer machine-readable media, such as non-transitory computer machine-readable storage media (e.g., magnetic disks; optical disks; random access memory; read only memory; flash memory devices; phase-change memory) and transitory computer machine-readable communication media (e.g., electrical, optical, acoustical or other form of propagated signals—such as carrier waves, infrared signals, digital signals, etc.).

In addition, such electronic devices typically include a set of one or more processors coupled to one or more other components, such as one or more storage devices (non-transitory machine-readable storage media), user input/output devices (e.g., a keyboard, a touchscreen, and/or a display), and network connections. The coupling of the set of processors and other components is typically through one or more busses and bridges (also termed as bus controllers). The storage device and signals carrying the network traffic respectively represent one or more machine-readable storage media and machine-readable communication media. Thus, the storage device of a given electronic device typically stores code and/or data for execution on the set of one or more processors of that electronic device. Of course, one or more parts of an embodiment of the invention may be implemented using different combinations of software, firmware, and/or hardware. Throughout this detailed description, for the purposes of explanation, numerous specific details were set forth in order to provide a thorough understanding of the present invention. It will be apparent, however, to one skilled in the art that the invention may be practiced without some of these specific details. In certain instances, well known structures and functions were not described in elaborate detail in order to avoid obscuring the subject matter of the present invention. Accordingly, the scope and spirit of the invention should be judged in terms of the claims which follow.

What is claimed is:

1. An apparatus comprising:
one or more memory and/or storage devices to store quantum computation specifications and hardware-specific constraints associated with a quantum processor; and
a quantum circuit synthesizer to generate a hardware-optimal quantum circuit based on the quantum computation specifications and the hardware-specific constraints.

2. The apparatus of claim 1 wherein the quantum circuit synthesizer comprises a hardware-specific analysis engine to identify relevant hardware-specific data based on the hardware-specific constraints and the quantum computation specifications.

3. The apparatus of claim 2 wherein to identify relevant hardware-specific data, the hardware-specific analysis engine is to determine whether and/or to what extent a specific hardware constraint will have with respect to implementation of the quantum computation specifications.

4. The apparatus of claim 2 further comprising:
a database or other storage implementation to store quantum gate/circuit data;
a quantum circuit generation engine of the quantum circuit synthesizer to use at least a portion of the quantum gate/circuit data to generate the hardware-optimal circuit based on the quantum computation specifications and the relevant hardware-specific data.

5. The apparatus of claim 1 wherein the hardware-specific constraints are to be provided by a user, read from a database in which hardware-specific data is stored for different quantum processors, and/or determined automatically through running test scripts on the quantum processor.

6. The apparatus of claim 1 wherein the hardware-specific constraints include arrangements and distances between qubits of a quantum processor, parallel processing capabilities of the quantum processor and/or a qubit controller, and/or qubit specific characteristics related to quantum control and/or measurements.

7. The apparatus of claim 1 further comprising:
execution circuitry to implement the hardware-optimal quantum circuit within a quantum runtime to generate sequences of qubit control commands.

8. The apparatus of claim 7 further comprising:
a quantum controller to generate corresponding sequences of analog control pulses to manipulate the qubits of the quantum processor in response to the sequences of qubit control commands.

9. The apparatus of claim 7 wherein the sequences of qubit control commands are to specify a sequence of parameterized Pauli rotations to one or more qubits of the quantum processor.

10. The apparatus of claim 9 further comprising:
a qubit measurement unit comprising measurement discrimination circuitry/logic to measure values of one or more of the qubits; and
quantum error correction circuitry/logic to perform quantum error corrections on the values if an error is detected.

11. A method comprising:
storing quantum computation specifications and hardware-specific constraints associated with a quantum processor in one or more memory devices and/or storage devices; and
generating a hardware-optimal quantum circuit based on the quantum computation specifications and the hardware-specific constraints.

12. The method of claim 11 further comprising:
identifying relevant hardware-specific data based on the hardware-specific constraints and the quantum computation specifications.

13. The method of claim 13 further comprising:
determining whether and/or to what extent a specific hardware constraint will have with respect to implementation of the quantum computation specifications to identify relevant hardware-specific data.

14. The method of claim 12 further comprising:
storing quantum gate/circuit data in a database or other storage device;
using at least a portion of the quantum gate/circuit data to generate the hardware-optimal circuit.

15. The method of claim 11 wherein the hardware-specific constraints are to be provided by a user, read from a database in which hardware-specific data is stored for different quantum processors, and/or determined automatically through running test scripts on the quantum processor.

16. The method of claim 11 wherein the hardware-specific constraints include arrangements and distances between qubits of a quantum processor, parallel processing capabilities of the quantum processor and/or a qubit controller, and/or qubit-specific characteristics related to quantum control and/or measurements.

17. The method of claim 11 further comprising:
generate sequences of qubit control commands in response to implementing the hardware-optimal quantum circuit within a quantum runtime.

18. The method of claim 17 further comprising:
generating corresponding sequences of analog control pulses to manipulate the qubits of the quantum processor in response to the sequences of qubit control commands.

19. The method of claim 17 wherein the sequences of qubit control commands are to specify a sequence of parameterized Pauli rotations to one or more qubits of the quantum processor.

20. The method of claim 19 further comprising:
measuring values associated with one or more of the qubits;
performing error correction on the values to generate corrected values if an error is detected; and
storing results comprising the values and/or the corrected values.

21. A machine-readable medium having program code stored thereon which, when executed by a machine, causes the machine to perform the operations of:
storing quantum computation specifications and hardware-specific constraints associated with a quantum processor in one or more memory devices and/or storage devices; and
generating a hardware-optimal quantum circuit based on the quantum computation specifications and the hardware-specific constraints.

22. The machine-readable medium of claim 21 further comprising program code to cause the machine to perform the operations of:
identifying relevant hardware-specific data based on the hardware-specific constraints and the quantum computation specifications.

23. The machine-readable medium of claim 23 further comprising program code to cause the machine to perform the operations of:
determining whether and/or to what extent a specific hardware constraint will have with respect to implementation of the quantum computation specifications to identify relevant hardware-specific data.

24. The machine-readable medium of claim 22 further comprising program code to cause the machine to perform the operations of:
storing quantum gate/circuit data in a database or other storage device;
using at least a portion of the quantum gate/circuit data to generate the hardware-optimal circuit.

25. The machine-readable medium of claim 21 wherein the hardware-specific constraints are to be provided by a user, read from a database in which hardware-specific data is stored for different quantum processors, and/or determined automatically through running test scripts on the quantum processor.

26. The machine-readable medium of claim 21 wherein the hardware-specific constraints include arrangements and distances between qubits of a quantum processor, parallel processing capabilities of the quantum processor and/or a qubit controller, and/or qubit-specific characteristics related to quantum control and/or measurements.

27. The machine-readable medium of claim 21 further comprising program code to cause the machine to perform the operations of:
generate sequences of qubit control commands in response to implementing the hardware-optimal quantum circuit within a quantum runtime.

28. The machine-readable medium of claim 27 further comprising program code to cause the machine to perform the operations of:
generating corresponding sequences of analog control pulses to manipulate the qubits of the quantum processor in response to the sequences of qubit control commands.

29. The machine-readable medium of claim 27 wherein the sequences of qubit control commands are to specify a sequence of parameterized Pauli rotations to one or more qubits of the quantum processor.

30. The machine-readable medium of claim 29 further comprising program code to cause the machine to perform the operations of:
measuring values associated with one or more of the qubits;
performing error correction on the values to generate corrected values if an error is detected; and
storing results comprising the values and/or the corrected values.
